(19) United States
(12) Patent Application Publication
(10) Pub. No.: US 2007/0085715 A1
(43) Pub. Date: Apr. 19, 2007

(54) METHOD AND APPARATUS FOR GENERATING CODEWORDS AND SETS OF CODEWORDS WHICH ARE USEFUL FOR BOTH COHERENT AND NON-COHERENT CHANNEL SOUNDING AND RANGING AND ALSO HAVE GOOD AUTO CORRELATION, CROSS CORRELATION AND SPECTRAL PROPERTIES

(75) Inventor: Michael McLaughlin, Dublin (IE)

Correspondence Address: MICHAEL MCLAUGHLIN, 25 MEADOWFIELD, SANDYFORD, DUBLIN, D18, IE

(73) Assignee: Michael McLauglhlin, Dublin (IE)

(21) Appl. No.: 11/309,222

(22) Filed: Jul. 13, 2006

Related U.S. Application Data
(60) Provisional application No. 60/595,597, filed on Jul. 19, 2005.

(51) Int. Cl. H03M 7/34

(52) U.S. Cl. 341/51

(57) ABSTRACT

The invention describes a method and device for designing a set of codewords, which have good properties for use in communication systems. These codeword sets are useful because they provide advantages to a communication system that uses them in that they result in lower error rates in the receiver. The method for designing the codes is to take a good set of codes with perfect periodic autocorrelation and manipulate it so as to transform it into a better code-set, for example a code-set with higher mean Golay merit factor, lower spectral peak to average ratio and lower mean cross correlation.

In the following description, certain specific details of the disclosed embodiment such as architecture, example codes, interfaces and techniques, etc, are set forth for purposes of explanation rather than limitation, so as to provide a clear and thorough understanding of the present invention. However, it should be understood readily by those skilled in this art, that the present invention may be practiced in other embodiments which do not conform exactly to the details set forth herein, without departing significantly from the spirit and scope of this disclosure. Further, in this context, and for the purposes of brevity and clarity, detailed descriptions of well-known apparatus, circuits and methodology have been omitted so as to avoid unnecessary detail and possible confusion

### BACKGROUND OF THE INVENTION

Periodic Autocorrelation

It is well known by those skilled in the art, that codes which have so called perfect periodic autocorrelation are useful for channel sounding. If a code has perfect autocorrelation, then its periodic autocorrelation has one peak and is zero everywhere else.

Auto correlation is the cross correlation of a signal with itself. Say for example a code is of length N. Its periodic autocorrelation can be calculated by multiplying every element of it by every element of the same code, circularly shifted by a phase offset and summing the results of this multiplication. This is done at all possible phases.

The periodic autocorrelation R at lag j for signal xₙ is
R(j)=Σₙxₙxₙ₋ⱼ

where Σₙ indicates the sum over all n.

Merit Factor

Another desirable property for a code is that it has low aperiodic autocorrelation side lobes. This is desirable especially in codes used to send data with Direct Sequence modulation. The lower the autocorrelation side lobes, the lower the amount of energy that spills over into adjacent symbols and so the lower the ISI produced by the codes themselves.

A commonly used measure of how good the code is in this respect is known as the Golay Merit Factor (GMF) or often simply the Merit Factor.

The Merit Factor is a measure of the quality of the autocorrelation function of a code. To calculated the merit factor the aperiodic autocorrelation function is calculated and then the merit factor is the ratio of the square of the central term to the sum of the squares of the off-peak terms.

This measure was introduced by M. J. E. Golay in [3].

The binary sequences with the highest known Merit Factors are the length 13 and 11 Barker sequences with Merit factors of 14.08 and 12.10 respectively. By comparison, the mean Golay merit factor of the length 32 Walsh-Hadamard matrix is 0.194.

A code with perfect periodic autocorrelation, known here as a PAC code, is then a code where R(j) is zero for all j except when j=0.

A family of ternary sequences with perfect periodic autocorrelation was discovered by Valery Ipatov [1] and extended by Høholdt and Justesen [2]. There are many sequences in this family, for example, lengths 7, 13, 21, 31, 57, 63, 73, 91, 127, 133, 183, 273, 307, 381, 511, 553, 651, 757, 871, 993, 1057, 1407, 1723.

Cross Correlation

When a communications system uses a set of codewords and the different codewords within that set are used for different purposes, e.g. to represent different data, or to provide isolation between different channels, it is desirable for these codewords to have low cross correlation with each other. This will reduce the chance of a receiver correlator being triggered by the wrong code. The wrong code could be present because, for example, there are echoes or reflections present of previously transmitted codes, or for example, two or more channels are being received by the receiver. Or the wrong code could be present because a different data code is being transmitted than is detected.

Spectral Peak to Average Ratio

For some communications systems the transmit power limits are set in terms of spectral power density. An example of this type of system is ultra wideband communications. The most useful part of the allowed transmit spectrum is flat. If a signal complies with these regulations, its worst case spectral density must stay below this straight line. If the signal spectrum has a peak anywhere, this peak must be kept below a certain limit by attenuating it and the rest of the signal. This effectively means that the whole signal must be penalised by any amount that the spectral peak to average ratio (SPAR) is above 0 dB. For this reason the SPAR needs to be kept as low as possible for codes used in these types of communications systems.

The invention here describes a new technique which can generate codes with perfect periodic autocorrelation and, among other properties, relatively large Golay Merit Factors, good cross correlation and low spectral peak to average ratios.

### DETAILED DESCRIPTION

Giving an example for length 31 codes and using the method outlined in [2] and using a base cyclic difference set: D={1, 5, 11, 24, 25, 2} with parameters L=31, k=6, λ=1 it is possible to generate 20 different PAC codes. They are generated by using pairs of difference sets rD and nD where the multipliers r and n are {−1, 2} and {−1, 1, 2, 3, 4, 8, 11, 12, 16, 17} respectively. These 20 are all different in that no two of them are the same even when cyclically shifted by any shift amount. Each of them is of length 31 and has 15 1s, 6 0s and 10 −1s.

As expected all the codes have perfect periodic auto-correlation but a further useful property is that if the absolute value of the code is taken i.e. substituting a 1 for −1. This modified code has 2 valued autocorrelation. In this case 25 and 20 are the two values. If we denote the original code OC and the modified code MC1 and make a further modification where all zeros in MC1 are replaced by −4. Denote this further modified code MC2. The periodic cross correlation of MC1 by MC2 is useful because it is zero valued at all points except for the zero shift point.

This is useful because a receiver which consists of an energy detector followed by a correlator can get an estimate of the channel impulse response. The code MC1 corresponds to the input to the receiver after the energy detector if the original unmodified code is being received. By using MC2 in the correlator the output is zero valued except at the zero shift point.

In the case outlined above the two values of autocorrelation are 25 and 20. Ideally these two values will be as far apart as possible. The further apart they are the less receiver energy is wasted in the lower value and the better the noise immunity is.

Another example for length 31 codes and using the method outlined in [2] and this time using a base cyclic difference set: D={1 2 3 4 6 8 12 15 16 17 23 24 27 29 30] with parameters L=31, k=15, λ=7.

In this case it is possible to generate 12 different PAC codes. They are generated by using pairs of difference sets rD and nD where the multipliers r and n are {3, 5} and {−1, 1, 3, 5, 7, 11} respectively. Again, these 12 are all different in that no two of them are the same even when cyclically shifted by any shift amount. This time each of them is also of length 31 but has 15 0s, 6 −1s and 10 1s. So they have 15 zero values and 16 non-zero values. The actual codes are as follows:

−−0−+00−++0000+−0+0+00+000+0++−

−−+−0++−000+0+0−+0+0000++00+00−

00−00−+0000−0++0−0+000+−+0++++−

00−0+−00+++−+000−+0+++0−0+0000−

0000−0+0−−+0++000−+−++00++0+00−

0000+0−0+++0+−000+−+++00−+0−00−

00+00++0000+0+−0+0+000−++0−+−−−

00+0++00++−+−000++0+−−0+0−0000−

++0+−00+−−0000++0−0−00+000+0++−

++0+000+00−0−0++0000−−+00−+0++−

++0+000+00+0+0−+0000++−00+−0−−−

++++0+−+000+0−0++0−0000+−00−00−

In this notation, − is minus one, 0 is zero and + is plus one.

Again, all the codes have perfect periodic auto-correlation but a further useful property is that if the absolute value of the code is taken i.e. substituting a 1 for −1. This modified code has 2 valued autocorrelation. In this case 16 and 8 are the two values. If we denote the original code OC and the modified code MC1 and make a further modification where all zeros in MC1 are replaced by −1. Denote this further modified code MC2. The periodic cross correlation of MC1 by MC2 is useful because it is zero valued at all points except for the zero shift point.

Again, this is useful because a receiver which consists of an energy detector followed by a correlator can get an estimate of the channel impulse response, but in this case there is greater noise immunity because the two values of the autocorrelation (of MC1) are further apart.

One aspect of the invention is to take a set of codes like these 12 length 31 PAC codes and generate a new set with better properties. The starting point in this example is the 12 codes, but it could be any set of codes with perfect periodic autocorrelation.

The following procedure may be used to generate better codes:

Step 1: Take any codeset H with m different codes of length n, this means that H is composed +1, −1 and 0. The codes should be different in that no code is the same as any other, even when cyclically shifted.

Step 2: For each code in H, i.e. each row of H, measure the SPAR and the GMF. (The SPAR can be measured by, for example, getting the FFT of a sequence consisting of the code with n zeros appended to each side of the code and dividing the peak power of the FFT bins by the mean power of the bins.). Do this for the code and for the code cyclical shifted by all possible shifts from 1 to n.

Step 3: Remember a small number, say w, of the best results. The way to define which is the best can be varied but one way would be to say one shift is better than another if the SPAR divided by the GMF is lower. This is because low SPAR is good and high GMF is good.

Step 4: Form a new matrix, K, the rows of which are the w best shifted codes from step 3. K now has w×m rows, each with a good code in it.

Step 5: Now we want to go back to K rows. We do this by choosing only one of the w that we selected earlier on, for each m rows. We will decide which one to take based on how low the cross correlation of the m we select is. We only take one from the w shifts because we want a matrix with low cross correlation and in general, the cross correlation between codes which are the same, but shifted, will be relatively high. To do this we measure the mean cross correlation between all possible combinations where only one of the w alternative possibilities is selected. If this is a very large number, a smaller w can be chosen in an earlier step, or a limited number of possibilities can be measured. We select the combination with the minimum mean cross correlation.

We now have a new matrix L with codes which have good SPAR, good GMF and good cross correlation. As an example this was done with the length 31 codes enumerated earlier and the following 12 codes were the result.

00+−0+0+00+000+0++−−−0−+00−++00 * **
0++00+00−−−+−0++−000+0+0−+0+000
−0++0−0+000+−+0++++−00−00−+0000
0+++−+000−+0+++0−0+0000−00−0+−0 *
+0−−+0++000−+−++00++0+00−0000−0 * **
00−+0−00−0000+0−0+++0+−000+−+++
+0+−0+0+000−++0−+−−−00+00++0000 *
−0000−00+0++00++−+−000++0+−−0+0
000+0++−++0+−00+−−0000++0−0−00+
000+00−0−0++0000−−+00−+0++−++0+ *
++−00+−0−−−++0+000+00+0+0−+0000
000+−00−00−++++0+−+000+0−0++0−0 * **
* Comination of 6 codes with best cross correlation
** Combination of 3 codes with best cross correlation

The mean GMF of the new codes is 5.12 compared to 2.55 for the original set. The mean SPAR is 2.31 compared to 3.04.

Applying this technique to the length 31 codes with only six zeros gave the following results.

The original 20 codes were this

−−++−++++−+0+++0−0−+0−−+−++00+−
−00−−+−++0+−0+0+++0−−+++−+++−+−
−+−+−0+00++−−0−+++++−+++−0++−0−
−+−+−++−−+0+−−−0+0+++++0−+00++−
−+++−0+00+−++0+−+−+++++−−0−−+0−
−+++−++00+−0+0++−+++0−−−−+−+0+−
0−−−0+−++−0+−+−+++−−+++00+0+++−
0−++0−+++−+++++−0−−++00+0−+−+−−
0+−−0−−+++++−+−+0++−+00+0−+++−−
0++−0+−+++0−++++−++−−−−00+0+−+−
+−−++++++−0+−+−0−0−++−−0++00++−
+−+0+00−−−−++−++++−0+++−+0−++0−
+−+++−+++−−0+++0+0−+0++−+−−00−−
+0−++++−−0−+−−−+0+0++00−++−+++−
+00++−+−−0+−0−0+++0+−++++−++−−−
+0+−+−−−−0+++−++0+0−+00++−+++−−
++00+−0+++++0+0−−−+0+−−++−+−+−−
++00++0−−++−0−0−+−+0−++++++−−+−
+++−++−00++0+0+−−−+−0−−++++−0+−
+++0+00+++−−+++−+−+0−++−+0−−−0−

After applying this technique to these codes the following new 20 codes were found

0−+0−−+−++00+−−−++−++++−+0+++0−
+−++0+−0+0+++0−−+++−+++−+−−00−−
++−−0−+++++−+++−0++−0−−+−+−0+00
−−0+0+++++0−+00++−−+−+−++−−+0+−
++++−−0−−+0−−+++−0+00+−++0+−+−+
+00+−0+0++−+++0−−−−+−+0+−−+++−+
−+++−−+++00+0+++−0−−−0+−++−0+−+
0+0−+−+−−0−++0−+++−+++++−0−−++0
+−+−+0++−+00+0−+++−−0+−−0−−++++
−00+0+−+−0++−0+−+++0−++++−++−−−
++−−0++00++−+−−++++++−0+−+−0−0−
−−−++−++++−0+++−+0−++0−+−+0+00−
−−00−−+−+++−+++−−0+++0+0−+0++−+
−++−+++−+0−++++−−0−+−−−+0+0++00
0−0+++0+−++++−++−−−+00++−+−−0+−
+−+++−−+0+−+−−−−0+++−++0+0−+00+
−+0+−−++−+−+−−++00+−0+++++0+0−−
−0−0−+−+0−++++++−−+−++00++0−−++
0++0+0+−−−+−0−−++++−0+−+++−++−0
+−+0−++−+0−−−0−+++0+00+++−−+++−

Quite a few variations on this technique are possible to change the outcome, some of these include for example:

i) Instead of improving the GMF and SPAR, some other quality could be improved, e.g. GMF only, SPAR only.

ii) In the final step where the mean cross correlation is minimized, some other measure could be minimized or maximized e.g. the maximum cross correlation could be minimized.

### REFERENCES

[1] V. P. Ipatov, “Ternary sequences with ideal autocorrelation properties” Radio Eng. Electron. Phys., vol. 24, pp. 75-79, October 1979.

[2] Tom Høholdt and Jørn Justesen, “Ternary sequences with Perfect Periodic Autocorrelation”, IEEE Transactions on information theory.

[3] “Sieves for Low Autocorrelation Binary Sequences”, IEEE Trans. Info. Th., vol. IT-23, pp. 43-51, January 1977

What is claimed is:

1. A method of communication where the transmitter transmits one or more ternary codes which have perfect periodic auto-correlation and which have been circularly shifted in order to optimize one of the properties of the code or to jointly optimize a function of more than one property of the code.

2. A method of claim 1 where the property being optimized is the Golay merit factor.

3. A method of claim 1 where one of the properties being jointly optimized is the Golay merit factor.

4. A method of claim 1 where one of the properties being jointly optimized is the spectral peak to average ratio.

5. A method of claim 1 where one of the properties being jointly optimized is the cross correlation with other ternary codes.

6. A communications device which includes a transmitter which transmits one or more ternary codes which have perfect periodic auto-correlation and which have been circularly shifted in order to optimize one of the properties of the code or to jointly optimize a function of more than one property of the code.

7. A communications device of claim 6 where the property being optimized is the Golay Merit Factor.

8. A communications device of claim 6 where one of the properties being jointly optimized is the Golay Merit Factor.

9. A communications device of claim 6 where one of the properties being jointly optimized is the spectral peak to average ratio.

10. A communications device of claim 6 where one of the properties being jointly optimized is the cross correlation with other ternary codes.
